(19) United States
(12) Patent Application Publication
(10) Pub. No.: US 2025/0201653 A1
(43) Pub. Date: Jun. 19, 2025

(54) ENHANCED COOLING PACKAGE FOR IMPROVED THERMAL MANAGEMENT FOR ELECTRICAL COMPONENTS

(71) Applicant: Vishay General Semiconductor LLC, Malvern, PA (US)

(72) Inventors: Huiying DING, Tianjin (CN); Longnan JIN, Tianjin (CN); Junkai BAI, Tianjin (CN); Jui Sen CHEN, New Taipei City (TW)

(73) Assignee: Vishay General Semiconductor LLC, Malvern, PA (US)

(21) Appl. No.: 18/686,082

(22) PCT Filed: Aug. 26, 2021
(86) PCT No.: PCT/US2021/047758

§ 371 Date: Feb. 23, 2024

(51) Int. Cl. H01L 23/367; H01L 21/48; H01L 21/56; H01L 23/00; H01L 23/31; H01L 23/495

(52) U.S. Cl. CPC H01L 23/3675; H01L 21/4878; H01L 21/565; H01L 23/3114; H01L 23/49555; H01L 24/40; H01L 24/32; H01L 2224/32245; H01L 2224/40245; H01L 2924/1203

(57) ABSTRACT

A electrical component package includes a folded heat sink for increased heat dissipation. The internal components of the package include an electrical component, a lead frame, a conductive clip, and terminal leads, which are electrically and mechanically interconnected. A packaging material is utilized to form a mold for encapsulating the internal components, the mold including a portion that is recessed. A heat sink is provided for heat dissipation and includes a first planar portion that extends from the lead frame, a second planar portion that is in spaced relation from the recessed portion of the mold, and a fold portion that is integral with and extends between the first and second planar portions.

### FIELD OF INVENTION

This application is generally related to heat sinks for electrical component packages and in more particular relates to heat sinks for greater heat dissipation capability by extending the heat sink about additional surface(s) of the package.

### BACKGROUND

Electrical components generate heat during normal operation, which must be continuously dissipated to ensure proper operation. Excessive heat can negatively affect the performance of an electrical system, as component parameter values generally vary with temperature. At particularly high temperatures, components may no longer perform within specification and may experience failure. As these systems and devices continue to decrease in size, the dimensions of their electrical components must also decrease accordingly. While the physical size of electric systems and their components have gotten smaller, the power requirements of these systems, and the heat generated therefrom, have not necessarily reduced in magnitude. Therefore, the heat generated by the components must be carefully managed in order to maintain safe and reliable operating temperatures for the systems.

Traditional semiconductor chip packages include both anode and cathode terminal leads on the bottom side of the package after semiconductor device is mounted on a printed circuit board. During operation, heat created inside the chip will be mainly distributed vertically through a bottom-located heat-sink to the outside air. The heat flow efficiency is influenced by factors including the properties of thermal conductivity of the components utilized on the semiconductor chip, thickness of the solder utilized, heat-sink mass, and other factors.

Therefore, it is desirable to provide electrical components such as semiconductors with enhanced heat dissipation capabilities. It is also desirable to provide electrical components with enhanced heat dissipation capability that are suitable for small form factors and can be incorporated into existing systems. It is also desirable to provide electrical components with enhanced heat dissipation capability that are economical in manufacture, durable in use, and efficient in operation.

### SUMMARY

Based on the foregoing, the present disclosure is directed to adding a new path to distribute the heat generated by the electrical component, such as a semiconductor to outside in order to enhance cooling capability, such as heat flow from the top side or the bottom side of the electrical component package by a heat sink extension.

In order to achieve this, an electrical component package is provided that includes a folded heat sink for increased heat dissipation. The internal components of the package may include a semiconductor die or chip, a lead frame, a conductive clip, and terminal leads, which are electrically and mechanically interconnected. A packaging material encapsulates the internal components, the packaging material including a recessed portion on a surface of the packaging material. A heat sink is provided for heat dissipation and includes a first planar portion that extends from the lead frame, a second planar portion that is in spaced relation from the recessed portion of the packaging material, and a fold portion that is integral with and extends between the first and second planar portions.

In another aspect, a method for dissipating heat from an electrical component package is provided. The method includes positioning an electrical component such as a semiconductor chip on a lead frame, and connecting a first end of a conductive clip to the top side of the electrical component and a second end of the conductive clip to a first terminal lead. The method includes encapsulating the semiconductor die and conductive clip, and at least a portion of the first terminal lead and a second terminal lead with a packaging material. A recessed portion is formed in the packaging material. The method includes forming a heat sink comprising a first planar portion extending from the lead frame, a second planar portion in spaced relation from the recessed portion of the packaging material to define a gap therebetween, and a fold portion extending between the first and second planar portions.

Other features which can be used individually or in various combinations with one another are described in detail below and in the claims.

### BRIEF DESCRIPTION OF THE DRAWING(S)

The foregoing Summary as well as the following Detailed Description will be best understood when read in conjunction with the appended drawings. In the drawings:

FIG. 1 is an enlarged top perspective view of a first embodiment of the electrical component package with a portion of the heat sink cut away to reveal the interrelationship of internal components;

FIG. 1A is an enlarged top perspective view of the first embodiment including an alternative heat sink provided without a cut-out portion;

FIG. 2 is an enlarged side view of the first embodiment electrical component package;

FIG. 2A is an enlarged side view of the first embodiment electrical component package including an alternative package enclosure provided without a recess portion;

FIG. 3 is an enlarged back view of the first embodiment electrical component package;

FIG. 4 is an enlarged top plan view in section of the first embodiment electrical component package;

FIG. 5 is an enlarged top perspective view of the first embodiment electrical component package;

FIG. 6 is an enlarge bottom perspective view of the first embodiment electrical component package;

FIG. 7 is an enlarged top perspective view of a second embodiment of the electrical component package with a portion of the heat sink cut away to reveal the interrelationship of internal components;

FIG. 7A is an enlarged top perspective view of the second embodiment of the electrical component package including an alternative heat sink provided without a cut-out portion;

FIG. 8 is an enlarged side view of the second embodiment electrical component package;

FIG. 8A is an enlarged side view of the second embodiment electrical component package including an alternative package enclosure provided without a recess portion;

FIG. 8B is an enlarged back view of the second embodiment electrical component package;

FIG. 9 is an enlarged top plan view in section of the second embodiment electrical component package;

FIG. 10 is an enlarged top plan view of the second embodiment electrical component package;

FIG. 11 is an enlarged bottom plan view of the second embodiment electrical component package;

FIG. 12 is an enlarged bottom plan view of the second embodiment electrical component package with encapsulation removed;

FIG. 13 is an enlarged side view of the electrical component package illustrating the manner for forming the heat sink into a folded configuration;

FIG. 14 is a flow chart illustrating one example of a method for manufacturing an electrical component package;

FIG. 15 is an enlarged side view of the electrical component package mounted to a printed circuit board and illustrating a manner for dissipating heat from the electrical component package;

FIG. 16 is an enlarged side view of a third embodiment of the electrical component package;

FIG. 17 is an enlarged perspective view of an external heat-sink mounted to an electrical component package; and,

FIG. 18 is an enlarged back view of the external heat-sink mounted to an electrical component package.

### DETAILED DESCRIPTION

Certain terminology is used in the following description for convenience only and is not limiting. The words top side, bottom side, first lateral side, second lateral side, front end and back end designate directions in the drawings to which reference is made. The following description provides specific details for a thorough understanding of embodiments of an electrical component package and a process for forming an electrical component package including a heat sink having a folded configuration for enhanced heat dissipation. Well-known structures and functions have not been shown or described in detail to avoid unnecessarily obscuring the description of the embodiments described herein. Figures are shown with cut-away portions for the purpose of explanation, illustration and demonstration purposes only, and are not intended to indicate that an element itself would be cut away in its final manufacture. Terms such as “substantially” or “generally” are intended to encompass +/−10% of an indicated value or tolerance from a designated shape.

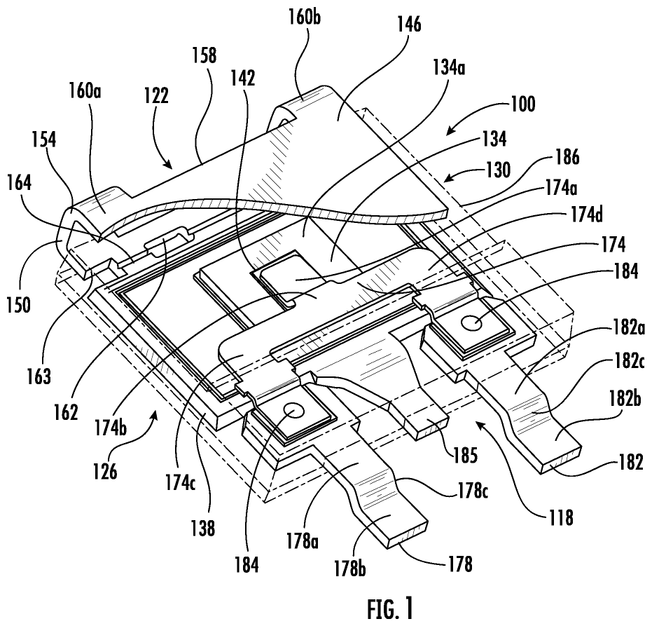

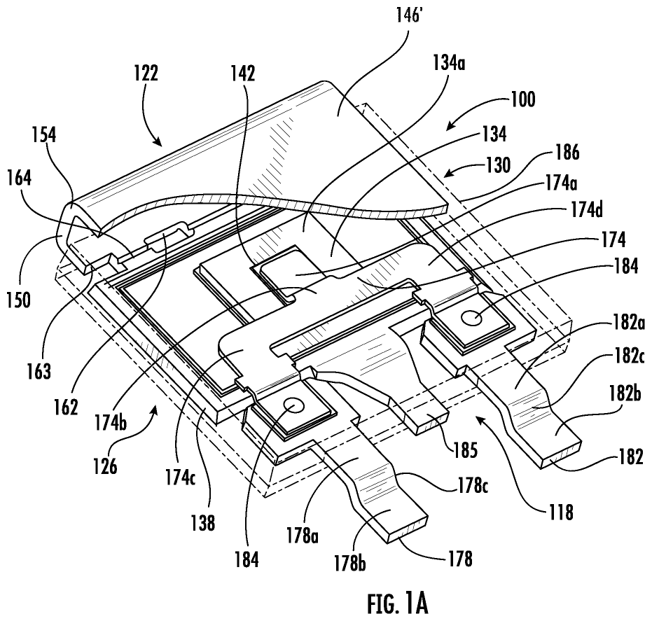

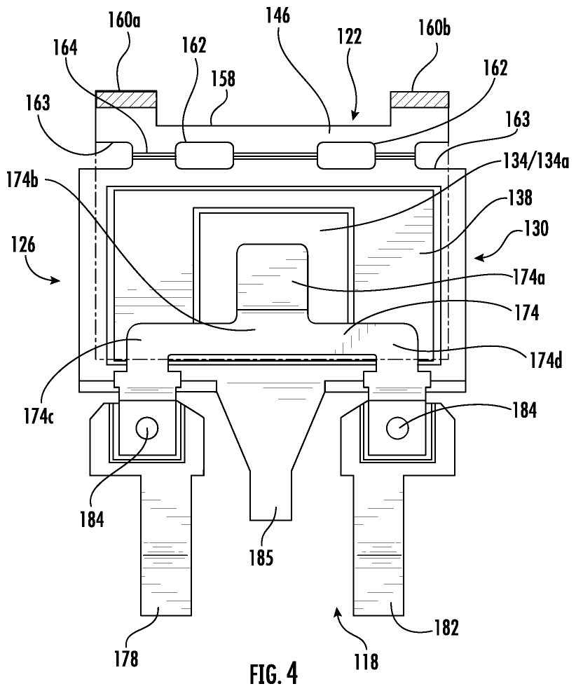

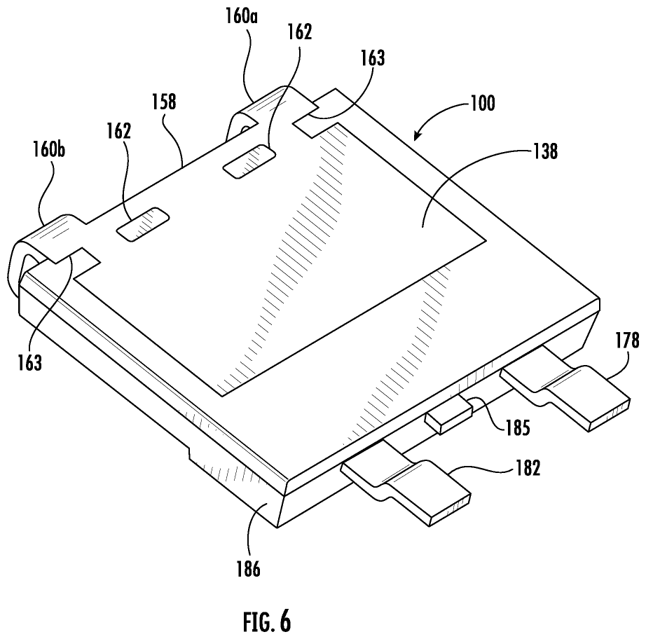

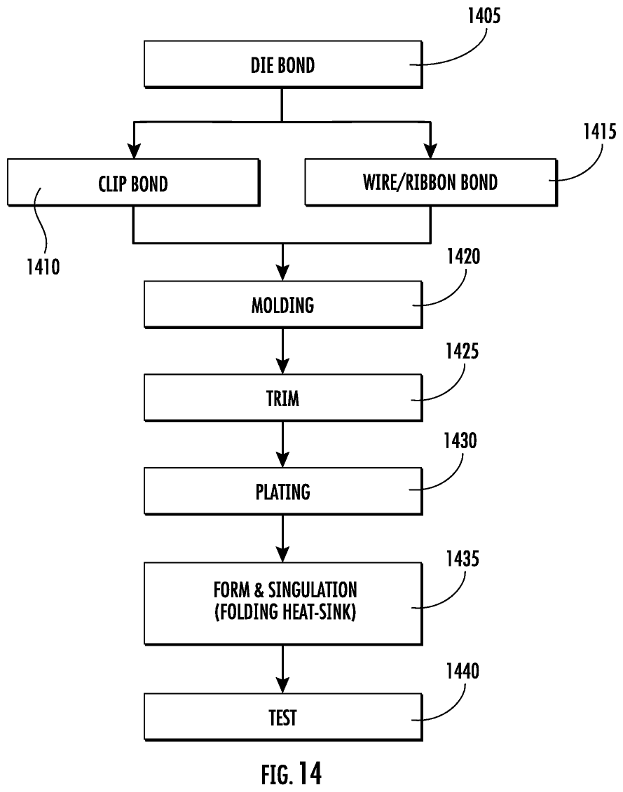

Referring now to FIGS. 1-6, there is shown a first embodiment of the electrical component package 100. The electrical component package 100 may be generally rectangular in shape and may include a top side 110 (FIG. 2), a bottom side 114 (FIG. 2), a front end 118 (FIG. 2), a back end 122 (FIG. 2), a first lateral side 126 (FIG. 1), and a second lateral side 130 (FIG. 1). The electrical component package 100 may be arranged for mounting to the surface of a printed circuit board, as best seen in FIG. 15. Under this first embodiment 100, the electrical component package 100 includes a centrally located electrical or electronic component in the form of a die or chip 134, such as a semiconductor chip, which can have a generally square or rectangular configuration, having an upward facing anode side 134a and a downward facing cathode side 134b (FIG. 2). In this embodiment, the cathode side 134b may be attached and bonded to a lead frame 138 extending along the bottom side 114 of the electrical component package 100. By way of example, the die or chip 134 may be a two terminal device such as a diode, or may be another type of electronic device suitable for inclusion in an electronic component package. The bottom surface 134b of the die or chip 134 may be attached to the upper surface of the lead frame 138 utilizing any suitable conductive material 142 including but not limited to solder paste, solder wire, conductive adhesive, or sinter paste. In this manner, electrical contact is established between the lead frame 138 and an electrode on a cathode side 134b of the die or chip 134. As best shown in FIGS. 1 and 4, the lead frame 138 may be in the form of a thin flat strip that may be generally rectangular in shape and extending substantially the entire width of the electrical component package 100 from the first lateral side 126 to the second lateral side 130. The lead fame 130 may also extend substantially all the way to the back end 122 of the electrical component package 100. The lead frame 138 may be formed from any suitable electrically conductive material such as copper (Cu), aluminum (Al), nickel, titanium (Ti), or alloys based on these metals.

A heat sink 146 is provided having a generally rectangular and folded configuration. The heat sink 146 may initially be provided as a flat, straight strip extending from the lead frame 138 towards the back end 122 of the electrical component package 100. As used herein, “flat” means “generally flat,” i.e., within normal manufacturing tolerances. As the heat sink 146 extends from the lead frame 138 towards the back end 122 of the electrical component package 100, it may be formed into a folded configuration, and extend along the top side 110 of the electrical component package 100 to a free end 146c.

More specifically, the heat sink 146 may include a first planar portion 146a extending from the lead frame 138 along the bottom side 114 of the electrical component package 100 and towards the back end 122 thereof. Once reaching the back end 122, the heat sink 146 may bend at a first corner 150 at an angle of approximately 90-degrees and extend upwardly for a predetermined distance to a second corner 154 located on the top side 110 of the electrical component package 100. Once reaching the second corner 154, the heat sink 146 may bend again at an approximately 90-degree angle, and extend along a second planar portion 146b along the top side 110 a predetermined distance to the free end 146c, giving the heat sink 146 a folded appearance. It should be understood that the folded appearance resulting from bending the heat sink 146 at two corners 150 and 154 is illustrative of a preferred embodiment, and merely exemplary and other shapes and configurations are contemplated for obtaining the folded appearance, including, for example, an arc, a semi-circle, or other shapes. The first and second planar portions 146a, 146b may be substantially parallel to one another.

At the back end 122 of the electrical component package 100, the heat sink 146 may include a cut-out portion 158 to define opposed arms 160a and 160b extending from the bottom side 114 to the top side 110. In the first embodiment, the cut-out portion 158 is shown as having a generally rectangular shape, although other shapes are contemplated. One purpose of the cut-out portion 158 may be to reduce the stress accumulated during the formation of corners 150, 154 to prevent fracture of the heat sink 146. By providing the cut-out portion 158, the amount of material in the region of the corners 150, 154 is substantially reduced which facilitates the bending of the heat sink material to form the corners 150, 154, thus reducing the possibility of abnormal bending or breakage of the heat sink 146 at the corners 150, 154 during the formation process. A further purpose of the cut-out portion 158 is to allow for enhanced air flow for heat dissipation from both sides of the second planar portion 146b. It should be appreciated that the cut-out portion 158 is an optional feature of the heat sink 146, and it may be included or excluded from the heat sink 146. As best shown in FIG. 1A, the cut-out portion (shown in FIG. 1 as 158) is not included as a feature of the heat sink 146′. Thus, the heat sink 146′ of FIG. 1A may be formed having a continuous, uninterrupted wall running along a portion of the back end 122 of the device. Otherwise, the embodiment of FIG. 1A may have the same configuration as the embodiment of FIG. 1.

The heat sink 146 may include one or more closed through holes 162, one or more open through holes 163, and a v-shaped notch 164 extending from the first lateral side 126 to the second lateral side 130. These features are included in the heat sink 146 for the purpose of receiving therein an epoxy or other suitable encapsulation material during a molding process (described below) to retain a portion of the heat sink 146 within the encapsulation material to enhance encapsulation material adhesion capability with the heat sink 146 and to reduce the risk of delamination.

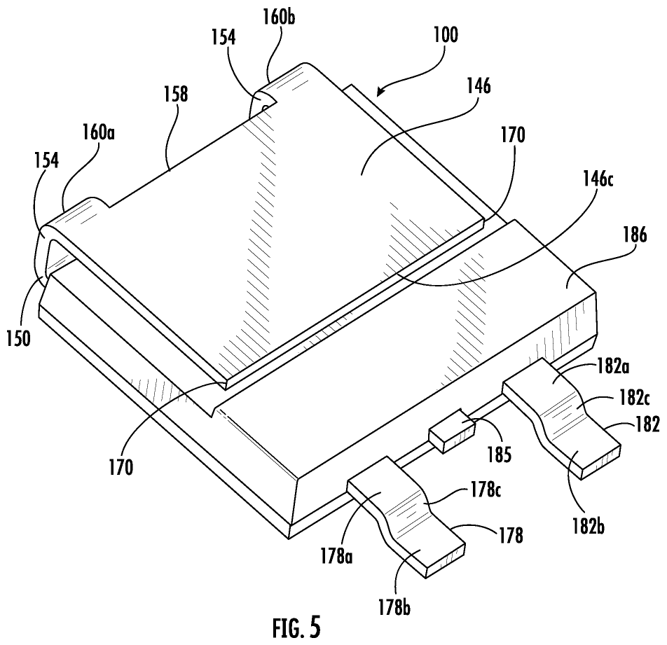

Referring now to FIG. 5, although the free end 146c of the heat sink 146 is illustrated as having sharp corners 170, it should be appreciated that these corners 170 may be somewhat or slightly rounded or curved. Acceptable metals for forming the heat sink 146 may be copper, aluminum, platinum, or other metals for use as heat sinks as are known in the art. The thickness of the heat sink 146 is determined based upon design considerations such as the product's electrical performance, thermal capability, cost and dimensional demand. A rough range for a preferred thickness of the heat sink 146 is from 0.2 mm to 2.0 mm. The generally rectangular shape of the heat sink 146 is illustrative of a preferred embodiment, and other configurations are contemplated to maximize use of available space on the electrical component package 100 in order to maximize heat dissipation. Also, it should be understood that although the heat sink 146 is shown in the figures as a single, unitary overall body, the heat sink 146 could be provided as separate or discrete portions, formed of the same or distinct materials, joined together to form the resulting heat sink 146.

Referring to FIGS. 1, 2 and 4, a clip 174 is provided to connect the anode side 134a of the die or chip 134 with terminal leads 178 and 182. The electrical component package 100 includes a packaging enclosure 186 (shown in broken line) for protecting components of the semiconductor package against moisture invasion and mechanical damage. The terminal leads 178 and 182 are shown as being separated from one another by a predetermined distance, and each terminal lead 178 includes a portion located within the packaging enclosure 186, and another portion located outside of the packaging enclosure 186 to enable electrical connection between the electrical component package 100 and the printed circuit board 190 (FIG. 15).

In particular, the clip 174 may include a free end 174a arranged to be bonded to the top surface, or anode side 134a, of the die or chip 134 utilizing any suitable conductive material 142 including but not limited to solder paste, solder wire, conductive adhesive, or sinter paste. As the clip 174 extends from the free end 174a towards the front end 118 of the package 100, the clip 174 may include a raised section 174b which acts as a bridge between the die or chip 134 and the terminal leads 178 and 182. As best seen in FIG. 1, the clip 174 includes branch portions 174c and 174d that extend in opposite directions and bend towards the terminal leads for connection thereto. Any suitable conductive material 184 such as a solder paste, solder wire, conductive adhesive, or sinter paste may be utilized to physically connect the branches 174c and 174d to the terminal leads 178 and 182, to provide an electrical connection between the die or chip 134 and the terminal leads 178 and 182. Under this first embodiment, as both terminal leads 178 and 182 are connected with the anode side 134a of the die or chip 134, the terminal leads are anode terminal leads.

As best shown in FIGS. 1 and 2, each terminal lead 178 and 182 includes an upper generally horizontal portion 178a, 182a, a lower generally horizontal free end 178b, 182b, and a bend portion 178c, 182c disposed therebetween. As best shown in FIG. 15, the lower generally horizontal free ends 178b, 182b of the terminal leads 178, 182 are arranged to contact the top surface of the printed circuit board 190 when the electrical component package 100 is mounted thereto.

The clip 174 may be formed of any suitable material such as aluminum, copper, silver, gold, or a metal alloy. As an alternative to the clip 174, a wire or ribbon may be utilized, the wire or ribbon being formed of a suitable material such as aluminum, copper, silver, gold, or a metal alloy. The electrical component package 100 may include a central pin 185 disposed centrally between the terminal leads 178 and 182. As best seen in FIG. 2, the central pin 185 extends from its free end, it bends downwardly to couple with the lead frame 138. The central pin 185 may be in the same plane as the upper generally horizontal portions 178a, 182a of the terminal leads 178 and 182.

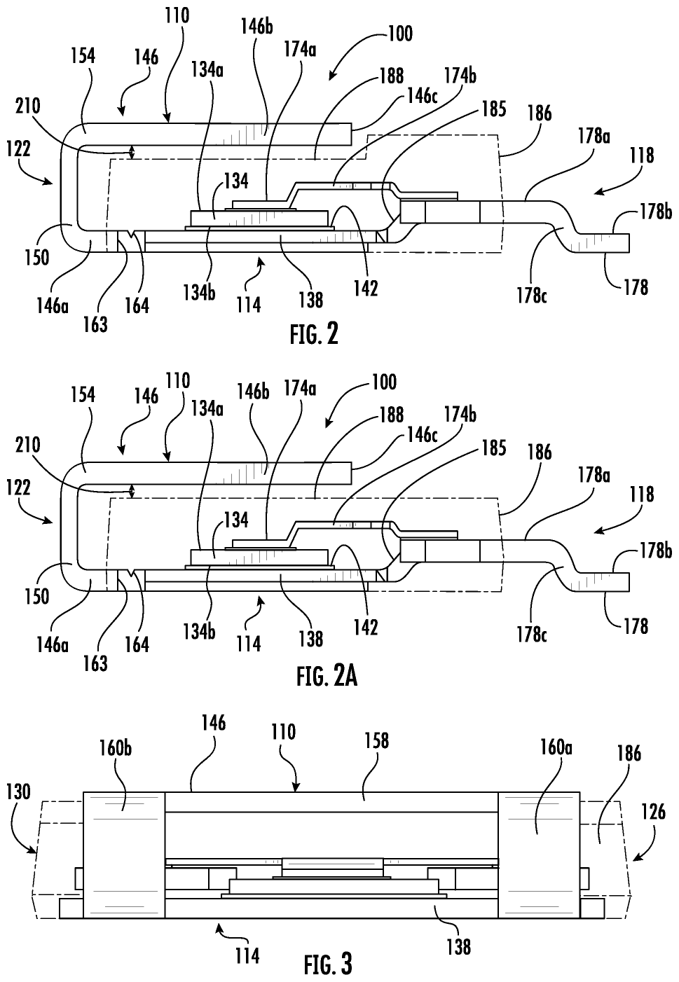

As best seen in FIGS. 2 and 3, after the clip 174 has been bonded in place, the packaging enclosure 186 may be formed around the components of the semiconductor package to protect against moisture invasion and mechanical damage. In particular, the entire die 134, the lead frame 138, a portion of the heat sink 146, the entire clip 174, the conductive material 142, 184, and a portion of the lead terminals 178 and 182 may be encased or encapsulated in an epoxy or other suitable compound as appropriate to the electrical component package. As best shown in FIG. 2, the package enclosure 186 may be formed to include a recessed portion 188. The second planar portion 146b of the heat sink 146 may extend within the recessed portion 188 and be positioned therein to maintain a distance or gap 210 between the second planar portion 146b of the heat sink 146 and the recessed portion 188 of the package enclosure 186 to allow for added heat dissipation during operation of the electrical component package. The gap 210 may also serve to provide space and prevent contact between the package enclosure 186 and the second planar portion 146b located in close proximity with the package enclosure 186 to avoid damage to the package enclosure 186. The second planar portion 146b may preferably be substantially coextensive with and covering the recessed portion 188. In addition, preferably, there may be a small gap between the free end 146c of the heat sink 146 and the vertical edge of the recessed portion 188 adjacent to the free end 146c. Once the compound has cured, it may be trimmed to remove flash created during the molding process. In addition, useless bars on the lead frame 138 may be removed as part of the trimming process.

The recessed portion 188 has a depth that is preferably between 80% and 150% of a thickness of the second planar portion 146b of the heat sink 146. More preferably, the depth is between 100% and 120% of this thickness. Additionally, the distance or gap 210 is preferably in a range of 30% to 80% of a thickness of the second planar portion 146b of the heat sink 146. More preferably, the distance or gap 210 is between 40% and 60% of this thickness. The size of the gap 210 impacts the overall thickness of the electrical component package 100. Thus, a smaller gap 210 is preferred, for example, greater than 0 mm.

It should be appreciated that the recessed portion 188 is an optional feature of the package enclosure 186, and it may or may not be included with the package enclosure 186. As best shown in FIG. 2A, the package enclosure 186 is shown as not including such a recessed portion. Under this configuration, the second planar portion 146b of the heat sink 146 may be positioned to maintain a distance or gap 210 between the second planar portion 146b of the heat sink 146 and the package enclosure 186 for the reasons discussed above.

Once the package enclosure 186 is trimmed, utilizing a suitable forming tool, the terminal leads 178, 182 may be formed from a substantially straight configuration, to the bent configuration including the upper generally horizontal portion 178a, 182a, the lower generally horizontal free end 178b, 182b, and the bend portion 178c, 182c disposed therebetween.

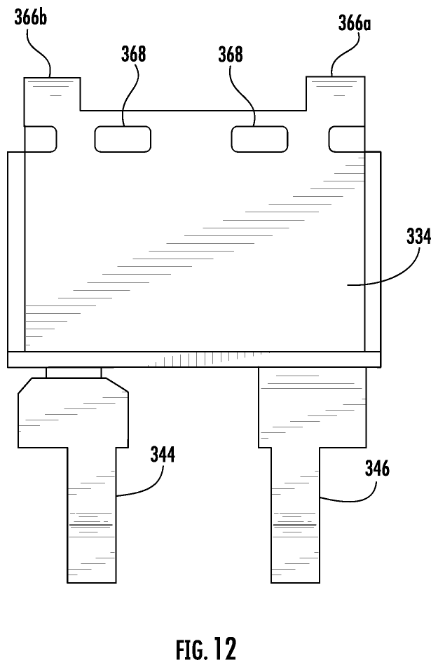

As best shown in FIGS. 1, 2 and 13, the formation of the heat sink 146 from a flat, straight strip extending from the lead frame 138 to its free end 146c, to its folded configuration is illustrated in a series of progressive steps. As used herein, “flat” means “generally flat,” i.e., within normal manufacturing tolerances. As best shown in FIG. 13, utilizing a suitable forming tool, the heat sink 146 may be folded in the several steps to form corners 150, 154, as indicated at steps 1305, 1310, 1315, 1320, 1325, and 1330. Step 1305 shows an initial generally flat configuration after encapsulation. Step 1310 shows an initial folding up of the second planar portion 146b as well as the arms 160a and 160b. Step 1315 shows that both of the corners 150, 154 are partially formed as the bending continues. Steps 1320 and 1325 show the further bending over of the second planar portion 146b toward a position parallel to and offset from the first planar portion 146a, as the corners 150, 154 move into their final position, and Step 1330 shows the final position of the second planar portion 146b partially in the recessed portion 188 of the package enclosure 186. Once the formation is completed, the heat sink 146 extends from the lead frame 138 on the bottom side towards the back end 122 and folds over the top side 110 of the electrical component package 100 as described in detail above.

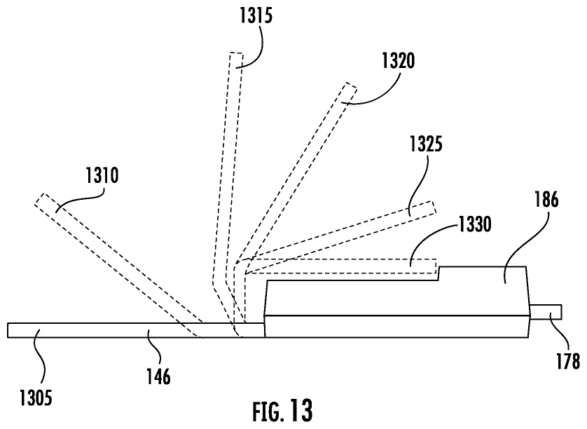

FIG. 14 is a flowchart illustrating one example of a method for forming a electrical component package having a folded heat sink. At block 1405, at the “die bond” step, the bottom surface of a die or chip 134 is attached and bonded to the lead frame 138 utilizing any suitable conductive material 142, as described previously. The bottom surface of the die or chip 134 may be either the cathode or, alternatively, the anode side of the die or chip, as is appropriate to the device. At block 1410, at the “clip bond” step, a clip 174 having a free end 174a is bonded to the top surface of the die or chip 134 utilizing a suitable conductive material, as described previously. As the clip 174 extends from its free end 174a, it branches and may be bonded to the two terminal leads 178 and 182 utilizing a suitable conductive material, as described above. In other embodiments, the clip may be bonded to just one of the terminal leads 178, 182, where the other terminal lead is in contact with the lead frame. At block 1415, at the “wire/ribbon bond” step, as an alternative to the clip 174, a wire or ribbon may be employed. At block 1420, at the “molding” step, a packaging enclosure 186 may be molded around all or a portion of the components of the electrical component package 100 to protect against moisture invasion and mechanical damage. At block 1425, at the “trim” step, the packaging enclosure may be trimmed. At block 1430, at the “plating” step, the electrical component package 100 may be plated. At block 1435, at the “form and singulation (folding heat sink)” step, the heat sink 146, as it extends from the lead frame 138 may be folded from the bottom of the electrical component package and over the top thereof, for example, using a suitable forming tool. Also, the terminal leads 178 and 182 may be formed to include generally horizontal free ends 178b and 182b, as described previously, to contact the surface of a printed circuit board 190 (FIG. 15) when the electrical component package is mounted thereto. At block 1440, the “test” step, the finished electrical component package 100 including the folded heat sink may be tested.

Referring now to FIG. 15, once the completed electrical component package 100 is mounted to the surface of the printed circuit board 190, the generally horizontal free ends of the terminal leads 178b, 182b are arranged to contact the top surface of the printed circuit board 190 and as indicated by arrows 194, act to dissipate heat from the electrical component package 100. Similarly, the lead frame 138 and a portion of the heat sink 146 is arranged to contact the top surface of the printed circuit board 190 to provide heat dissipation from the electrical component package 100 as indicated by arrows 198. In addition, as the heat sink 146 turns the corners 150 and 154, and extends across the top side 110 of the package 100, it dissipates heat away from the package 100 in directions indicated by arrows 202 and 206. The gap 210 also allows air flow for heat dissipation from the heat sink 146.

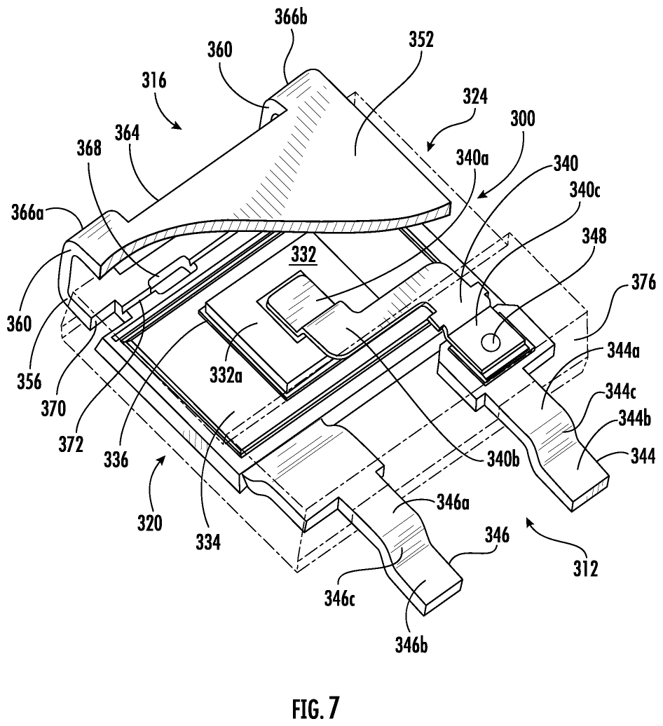

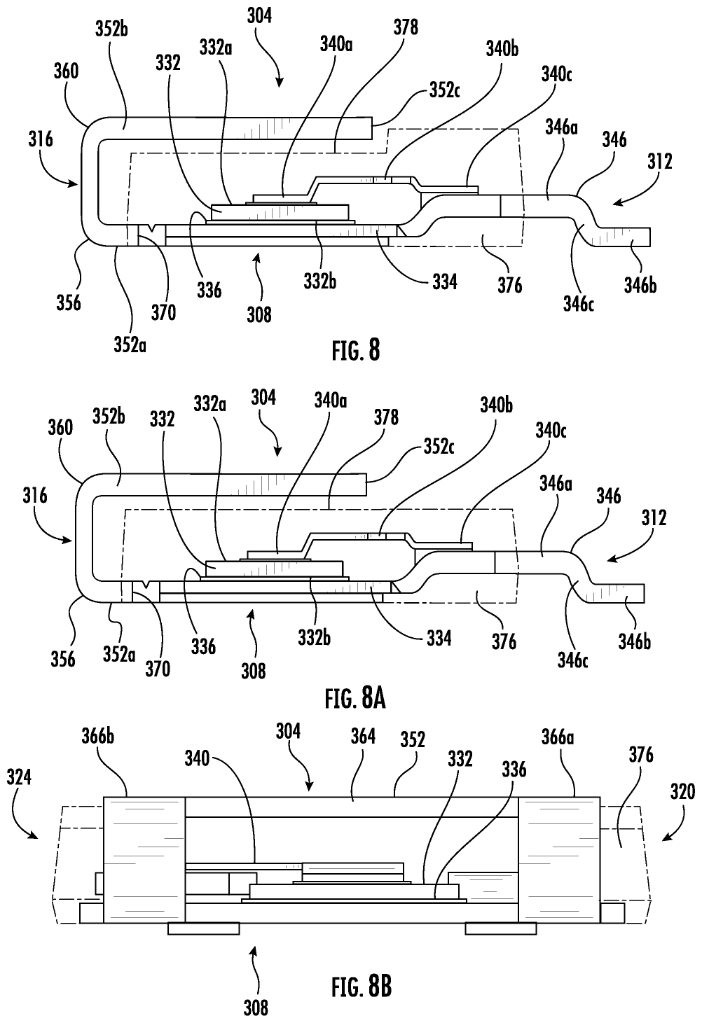

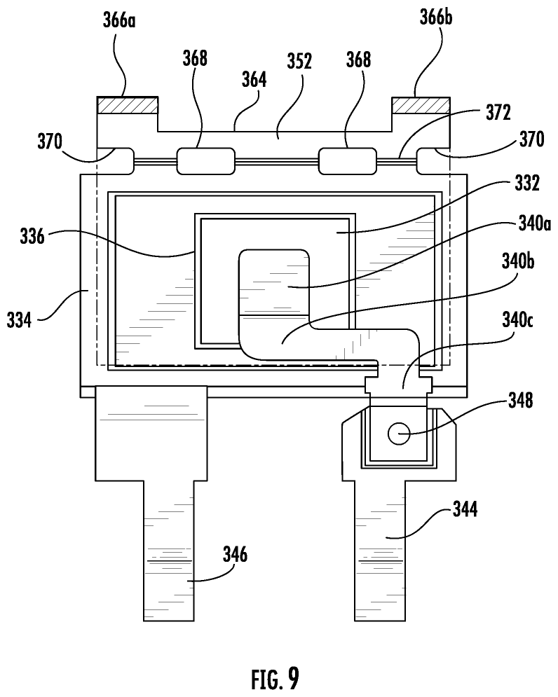

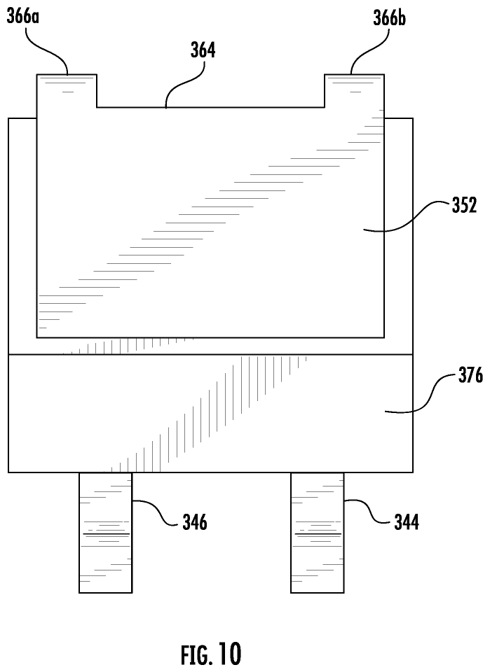

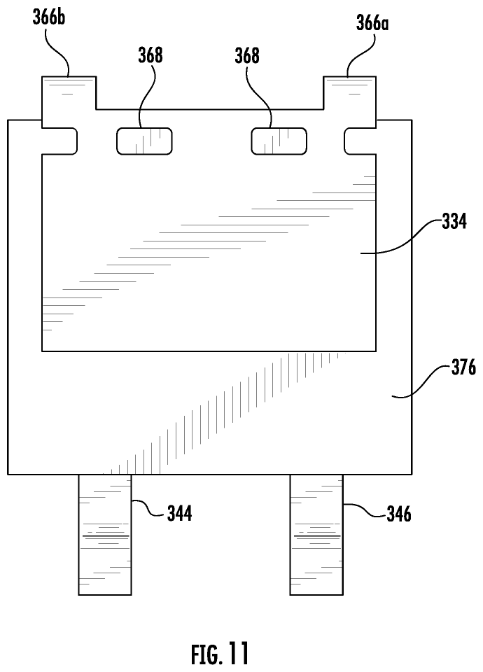

Referring now to FIGS. 7 through 12, there is shown a second embodiment of the electrical component package 300. As with the first embodiment 100, the electrical component package 300 includes a top side 304, a bottom side 308, a front end 312, a back end 316, a first lateral side 320, and a second lateral side 324. In this second embodiment, a die or chip 332 is mounted to a lead frame 334 with its anode side 332a facing upwardly and its cathode side 332b facing downwardly, where it is attached to the lead frame 334 by bonding as discussed in connection with the first embodiment. As with the first embodiment, the die or chip 332 may be a two terminal device such as a diode, and the bottom surface or cathode side of the die or chip 332 may be attached to the upper surface of the lead frame 334 utilizing any suitable conductive material 336 as discussed above to establish electrical contact to form a first terminal.

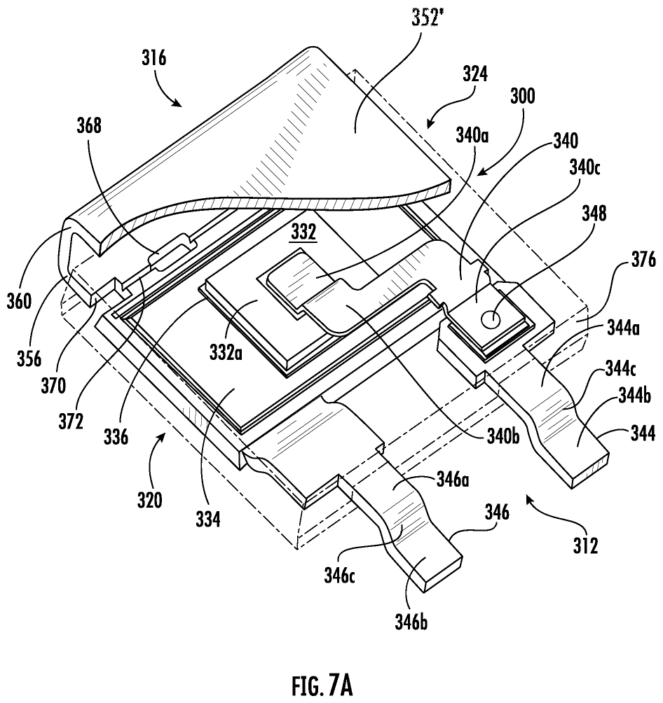

Under the second embodiment, a clip 340 has a generally reverse S-shaped configuration including a first free end 340a arranged for bonding to the top surface 332a, or anode side, of the die or chip 332. The clip 340 also may include a raised section 340b which acts as a bridge between the die or chip 332 and the terminal lead 344. As best shown in FIGS. 7 and 8, at its second free end 340c, the clip 340 is arranged to connect with the terminal lead 344 by bonding as discussed in connection with the first embodiment to provide an electrical connection between the die or chip 332 and the terminal 344. Thus, the terminal lead 344 is an anode terminal lead resulting from its connection with the anode side of the die or chip 332. As best shown in FIGS. 7 and 8, each terminal lead 344, 346 includes an upper generally horizontal portion 344a, 346a, a lower generally horizontal free end 344b, 346b, and a bend portion 344c, 346c disposed therebetween.

As with the first embodiment, a heat sink 352 is provided having a generally rectangular and folded configuration. As best shown in FIGS. 7-9, the heat sink 352 may extend from the lead frame 334 rearwardly towards the back end 316 of the semiconductor package 300. As the heat sink 352 extends towards the back end 316 of the semiconductor package 300, it may be formed into a folded configuration, and extend along the top side 304 of the semiconductor package 300 to a free end 352c. More specifically, as best shown in FIGS. 8 and 8B, the heat sink 352 may include a first planar portion 352a extending from the lead frame 334 along the bottom side 308 of the electrical component package 300 and towards the back end 316 thereof. Once reaching the back end 316, the heat sink 352 may bend at a first corner 356 at an angle of approximately 90-degrees and extend upwardly for a predetermined distance from the first corner 356 to a second corner 360 located on the top side 304 of the electrical component package 300. Once reaching the second corner 360, the heat sink 352 may bend or turn again at an approximately 90-degree angle, and extend along a second planar portion 352b from the second corner 360 along the top side 304 for a predetermined distance to its free end 352c as it approaches the front end 312 of the semiconductor package 300 giving the heat sink 352 a folded appearance. It should be understood that the folded appearance resulting from bending the heat sink 352 at two corners 356 and 360 is illustrative of a preferred embodiment, and merely exemplary and other shapes and configurations are contemplated for obtaining the folded appearance, including, for example, an arc, a semi-circle, or other shapes.

As shown in FIGS. 7, 8B, and 9 through 12, the second embodiment of the electrical component package 300 may include a large cut-out portion 364 provided for the purposes discussed in connection with the first embodiment, i.e., stress reduction and added heat dissipation. The cut-out portion 364 defines opposed arms 366a and 366b extending from the bottom side 308 to the top side 304. It should be appreciated that the cut-out portion 364 is an optional feature of the heat sink 352, and may or may not be included. For example, as best shown in FIG. 7A, the cut-out portion (shown in FIG. 7 as 364) is not included as a feature of the heat sink 352′ of the second embodiment electrical component package 300. Thus, the heat sink 352′ of FIG. 7A may be formed having a continuous, uninterrupted wall running along a portion of the back end 316 of the device. Otherwise, the embodiment of FIG. 7A may have the same configuration as the embodiment of FIG. 7.

As with the first embodiment, the heat sink 352 may include one or more closed through holes 368 and one or more open through holes 370 arranged for receiving therein epoxy or other suitable encapsulation material during a molding process to retain the heat sink 352 within the encapsulation material. In addition, as with the first embodiment, a v-shaped notch 372 may be provided to reduce the accumulation of stresses to prevent fracture during formation of the fold. The v-shaped notch 372 is shown extending from the first lateral side 320 to the second lateral side 324.

The folded heat sink 352 may be a cathode heat sink resulting from its connection with the cathode side 332b of the die or chip 332 through the lead frame 334. Referring now to FIGS. 7 and 8, the lead frame 334 is shown as contacting the cathode side 332b of the die or chip 332 and connecting with the terminal lead 346 which is a cathode terminal lead resulting from its connection with the cathode side 332b of the die or chip 332.

As an alternative under this embodiment, the die or chip 332 may be mounted to the lead frame 334 with its anode side 332a facing downwardly and bonded to the lead frame 334, and its cathode side 332b facing upwardly. Under this mounting orientation, the terminal lead 344 would be a cathode terminal lead as a result of its connection with the cathode side 332b of the die or chip 332, and the heat sink 352 would be an anode heat sink as a result of its connection with the anode side 332a of the die or chip 332. As mentioned in the first embodiment, as an alternative to the clip 340, a wire or ribbon may be utilized, formed of a suitable material as specified above.

As best seen in FIGS. 7 and 8, as with the first embodiment, after the clip 340 has been bonded in place, a packaging enclosure 376 (shown in broken line) may be formed around the components of the semiconductor device to protect against moisture invasion and mechanical damage. In particular, the die 332, the lead frame 334, a portion of the heat sink 352, the clip 340, the conductive material 336, and a portion of the terminal leads 344 and 346 may be encased or encapsulated in an epoxy or other suitable compound as appropriate to the electrical component package 300. As best shown in FIG. 8, the package enclosure 376 may include a recessed portion 378 having a configuration as described in the first embodiment. The second planar portion 352b of the heat sink 352 may extend within the recessed portion 378 of the packaging enclosure 376 to maintain a predetermined distance between the recessed portion 378 of the packaging enclosure 376 and the second planar portion 352b of the heat sink to permit for added heat dissipation during operation of the electrical component package.

It should be appreciated that the recessed portion 378 is an optional feature of the package enclosure 376, and it may or may not be included with the package enclosure 376. As best shown in FIG. 8A, the second embodiment electrical component package is shown as including a package enclosure 376 that does not include such a recessed portion. Under this configuration, the second planar portion 352b of the heat sink 352 may be positioned to maintain a distance or gap between the second planar portion 352b of the heat sink 352 and the package enclosure 376 for the reasons discussed above.

As with the first embodiment, utilizing a suitable forming tool, the heat sink 352 may be formed in several steps to form corners 356 and 360 from a flat, straight strip to a folded configuration as illustrated in FIG. 13. Once the formation is completed, the heat sink 352 extends from the bottom side and folds over the top side of the electrical component package 300 as described in detail above. Also, as described in the first embodiment, utilizing a suitable forming tool, the terminals leads 344 and 346 may be formed from a substantially straight configuration, to the bent configuration including the upper generally horizontal portion 344a, 346a, a lower generally horizontal free end 344b, 346b, and the bend portion 344c, 346c disposed therebetween. In this manner, the terminal leads 344, 346 may be placed in contact with the surface of the printed circuit board 190 (FIG. 15) when the completed electrical component package 300 is mounted thereto for heat dissipation. As described in the first embodiment, the folded heat sink 352 may provide heat dissipation from the electrical component package 300 in the directions of the arrows 198, 202, and 206.

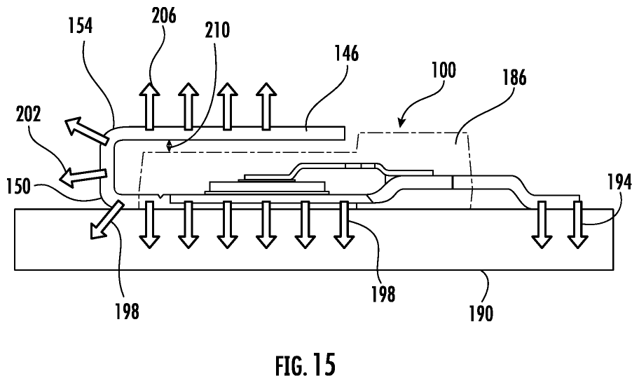

Referring now to FIG. 16, there is shown a side view of a third embodiment of the electrical component package 400 of the present invention. Unlike the first and second embodiments where the electronic components of the package are situated in proximity with the bottom side of the package, and the heat sink extends from the bottom side and folds over the top side, in this embodiment 400, the electronic components are situated in proximity with the top side 404 of the semiconductor package, and the heat sink 452 extends from the top side, and folds under and at least partially into a recess 477 at the bottom side of the package enclosure 476. As with the first and second embodiments, the recess 477 is optional. This third embodiment 400 also includes a bottom side 408, a front end 412, and a back end 416. A lead frame 434 extends across the top side 404 of the package 400 and a die or chip 432 is mounted to a bottom face of a lead frame 434, where it is attached to the lead frame 434 by bonding using a suitable conductive material 436, as discussed above. The die or chip 432 may be a two terminal device such as a diode. A clip 440, similar to the clip 174 or 340 above, includes a first free end 440a arranged for bonding to the bottom side of the die or chip 432 using a suitable conductive material 436. The clip 440 may include a trough section 440b which extends between the first free end 440a and a second free end 440c to connect the die or chip 432 to the terminal lead 444 as described in connection with the first two embodiments. The terminal lead 444 may include an upper generally horizontal portion 444a, a lower generally horizontal free end 444b, and a bend portion 444c disposed therebetween.

A heat sink 452 is provided having a generally folded configuration. The heat sink 452 is shown extending from the lead frame 434 at the top side 404 towards the back end 416 of the package 400 where the heat sink 452 may bend at a first corner 456 and extend downwardly for a predetermined distance to a second corner 460, and may turn again and extend along the bottom side 408 of the package 400 for a predetermined distance to its free end 452a to give the heat sink 452 a folded appearance. As with the first and second embodiments, the third embodiment of the electrical component package 400 may include a cut-out portion to define opposed arms extending from the top side 404 to the bottom side 408. In addition, as with the first and second embodiments, other features may be included such as the v-shaped notch 472 to reduce the accumulation of stresses to prevent fracture during formation of the fold. Also, the heat sink 452 may include one or more closed through holes and one or more open through holes 468 arranged for receiving therein epoxy or other suitable encapsulation material during a molding process to retain the heat sink 452 within the encapsulation material.

As discussed in the first and second embodiments, the die or chip 432 may be mounted to the lead frame 434 with either its anode side contacting the lead frame 434, or with its cathode side contacting the lead frame 434. The mounting orientation of the die or chip 432 on the lead frame 434 will determine whether the folded heat sink is a cathode or an anode. As mentioned earlier, as an alternative to the clip 440, a wire or ribbon may be utilized, formed of a suitable material as specified above.

As described in the first and second embodiments, after the clip 440 has been bonded in place, a packaging enclosure 476 (shown in broken line) may be formed around the components of the semiconductor device to protect against moisture invasion and mechanical damage. The package enclosure 476 may be formed to include a recessed portion 477 having the configuration described in the first embodiment.

As with the earlier embodiments, for example, using a suitable forming tool, the heat sink 452 may be formed in several steps to form corners 456 and 460 from a flat, straight strip to a folded configuration. Once the formation is completed, the heat sink 452 may extend from the top side and bend at corners 456 and 460 and extend adjacent to and at least partially in the recessed portion 477. A predetermined distance or gap may be maintained between the heat sink 452 and the recessed portion 477 to allow for added heat dissipation during operation of the electrical component package.

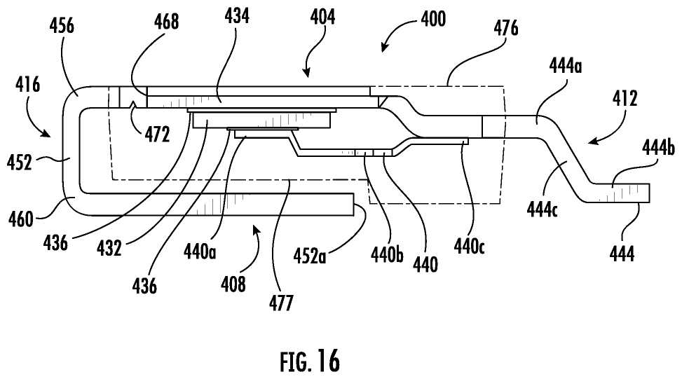

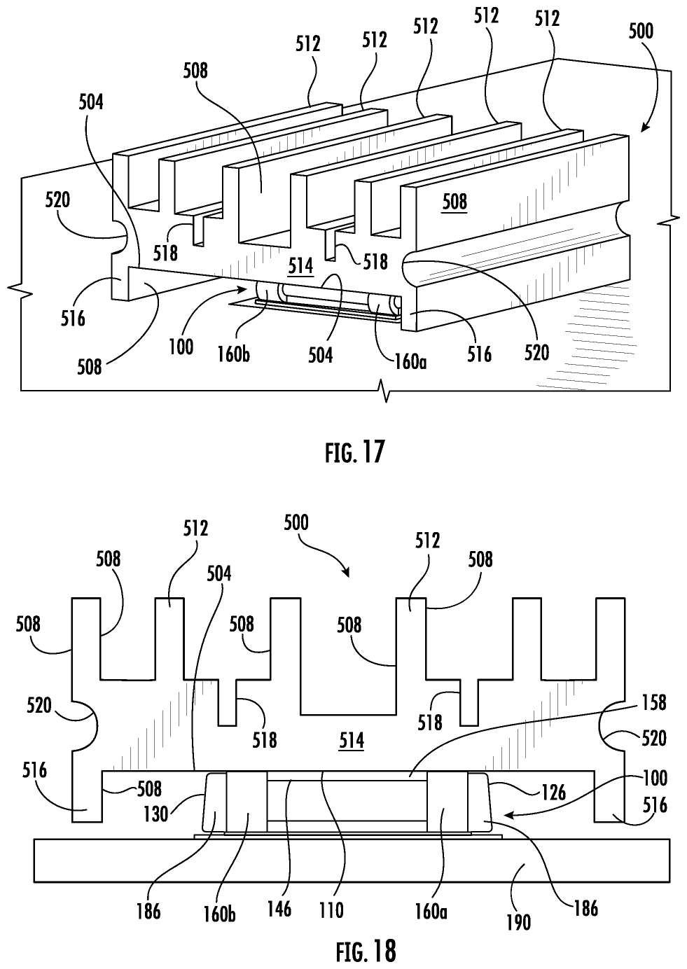

Referring now to FIGS. 17 and 18, there is shown therein an external heat-sink 500 arranged for use in combination with any of the embodiments of the electrical component package described above. As best shown in these figures, for example, an embodiment of the electrical component package 100 is shown placed in contact with a printed circuit board 190. The external heat-sink 500 may be provided to supplement or enhance the conductive cooling and thermal dissipation provided by the heat-sink 146 during operation of the electrical component package 100, such as for high power electrical components. The use of the external heat-sink 500 is optional, such that if heat dissipation is not an issue for a particular electrical component package, then use of the external heat-sink 500 may be disregarded. In addition, details relating to the design of the external heat-sink 500, including size and configuration as shown in the figures, are merely exemplary, and are presented for purposes of illustration only and are not intended to be limiting in any way.

In the figures, the external heat-sink 500 is shown positioned over the electrical component package 100, and is in contact with the top side 110 of the folded heat sink 146 thereof. The external heat-sink 500 may be formed of any suitable thermally conductive material, including suitable metals such as aluminum that is forged, or impact extruded.

The external heat-sink 500 includes a mounting surface 504 for receiving heat from the top side 110 of the heat sink 146 of the electrical component package 100. The external heat-sink 500 includes a plurality of heat radiating surfaces 508 for radiating the received heat to a coolant. The coolant may be in the form of a gas, such as ambient air, or may be a liquid. The heat radiating surfaces 508 may be formed into a plurality of parallel heat-dissipating fins 512. The fins 512 may extend upwardly a predetermined distance from a central region 514 located above the mounting surface 504. The fins 512 may extend away from the mounting surface 504 in a generally perpendicular direction, or in a direction that is vertical to the surface of the printed circuit board 190. The heat radiating surfaces 508 may also be formed into a plurality of heat-dissipating fins 516 that may extend downwardly from the central region 514 to approach, but not contact, the top surface of the printed circuit board 190. The heat radiating surfaces 508 may also be formed into a plurality of heat-dissipating grooves 518 formed in the central region 514. In combination, the surface area of the heat radiating surfaces 508 is greater than the surface area of the mounting surface 504. The surface area of heat-radiating surfaces 508 may preferably be twice or more the surface area of mounting surface 504, and preferably at least four times. Also, the major portion of fins 512 is situated within the footprint of mounting surface 504. In other words, the horizontal extent of fins 512 is substantially within the horizontal extent of mounting surface 504. The external heat-sink 500 may include additional features such as cut-out portions 520.

It is appreciated that a heat sink according to the invention may include one or more cut-outs, additional openings, or no cut-outs or additional openings, or variations in the shapes and sized of any cut-outs or openings.

It will be appreciated that the foregoing is presented by way of illustration only and not by way of any limitation. It is contemplated that various alternatives and modifications may be made to the described embodiments without departing from the spirit and scope of the invention. Having thus described the present invention in detail, it is to be appreciated and will be apparent to those skilled in the art that many physical changes, only a few of which are exemplified in the detailed description of the invention, could be made without altering the inventive concepts and principles embodied therein. It is also to be appreciated that numerous embodiments incorporating only part of the preferred embodiment are possible which do not alter, with respect to those parts, the inventive concepts and principles embodied therein. The present embodiment and optional configurations are therefore to be considered in all respects as exemplary and/or illustrative and not restrictive, the scope of the invention being indicated by the appended claims rather than by the foregoing description, and all alternate embodiments and changes to this embodiment which come within the meaning and range of equivalency of said claims are therefore to be embraced therein.

What is claimed is:

1. An electrical component package arranged for mounting on a printed circuit board, the electrical component package comprising:
an electrical component having a top side with at least one electrical contact and a bottom side with at least one electrical contact;
a lead frame arranged for receiving and electrically connecting to the bottom side of electrical component;
a conductive clip having a first end electrically connected to the top side of the electrical component and extending from the first end to electrically connect with at least a first terminal lead;
a second terminal lead extending from the electrical component package;
a packaging material encapsulating the electrical component and conductive clip, and at least a portion of the first and second terminal leads; and,
a heat sink comprising a first planar portion extending from the lead frame, a second planar portion in spaced relation from the packaging material defining a gap therebetween, and a fold portion extending between the first and second planar portions.

2. The electrical component package of claim 1, wherein the fold portion includes a cut-out portion to define opposed arms extending from the first planar portion to the second planar portion.

3. The electrical component package of claim 1, wherein the fold portion is integral with the first planar portion and the second planar portion.

4. The electrical component package of claim 1, wherein the heat sink includes at least one through hole for receiving the packaging material.

5. The electrical component package of claim 4, wherein the at least one through hole comprises a closed through hole.

6. The electrical component package of claim 1, wherein the first terminal lead is an anode terminal lead.

7. The electrical component package of claim 1, wherein the conductive clip electrically connects with the second terminal lead, and wherein the first and second terminal leads are both anode terminal leads.

8. The electrical component package of claim 1, wherein the first terminal lead is electrically connected to the conductive clip and is an anode terminal lead, and the second terminal lead is electrically connected to the lead frame, and is a cathode terminal lead.

9. The electrical component package of claim 1, wherein the first terminal lead and the second terminal lead extend to a position that is adapted to contact the printed circuit board.

10. The electrical component package of claim 1, wherein the top side of the electrical component is an anode, and the bottom side of the electrical component is a cathode, and wherein the folded heat sink is part of the cathode.

11. The electrical component package of claim 1, wherein the top side of the electrical component is a cathode, and the bottom side of the electrical component is an anode, and wherein the folded heat sink is part of the anode.

12. The electrical component package of claim 1, wherein the electrical component comprises a diode.

13. The electrical component package of claim 1, wherein the second planar portion of the heat sink is generally rectangular in shape.

14. The electrical component package of claim 1, additionally comprising a central pin situated between the first terminal lead and the second terminal lead.

15. The electrical component package of claim 1, wherein the first planar portion and the second planar portion of the heat sink are substantially parallel.

16. The electrical component package of claim 1, additionally comprising a top side and a bottom side, and wherein the first planar portion of the heat sink extends from the lead frame along the bottom side of the electrical component package, and wherein the second planar portion of the heat sink extends from the fold portion along the top side of the electrical component package.

17. The electrical component package of claim 1, additionally comprising a top side and a bottom side, and wherein the first planar portion of the heat sink extends from the lead frame along the top side of the electrical component package, and wherein the second planar portion of the heat sink extends from the fold portion along the bottom side of the electrical component package.

18. The electrical component package of claim 1, wherein the electrical component is a semiconductor chip.

19. The electrical component package of claim 1, additionally comprising an external heat sink arranged for positioning over the electrical component package and contacting the second planar portion of the heat sink of the electrical component package.

20. The electrical component package of claim 19, wherein the external heat sink is formed of a thermally conductive material.

21. The electrical component package of claim 1, wherein the packaging material includes a recessed portion.

22. A method for of dissipating heat from an electrical component package, the method comprising:
a. providing an electrical component having a top side and a bottom side;
b. positioning the bottom side of the electrical component on a lead frame;
c. providing a conductive clip having a first end and a second end,
d. connecting the first end of a conductive clip to the top side of the electrical component and connecting the second end of the conductive clip to at least a first terminal lead;
e. providing a second terminal lead positioned in the electrical component package;
f. encapsulating the electrical component and conductive clip, and at least a portion of the first and second terminal leads with a packaging material;
g. forming a recessed portion in a surface of the packaging material; and,
h. forming a heat sink comprising a first planar portion extending from the lead frame, a second planar portion in spaced relation from the recessed portion of the mold defining a gap therebetween, and a fold portion extending between the first and second planar portions.

23. The method of claim 22, further comprising a step of electrically connecting the conductive clip to the second terminal lead.

24. The method of claim 22, further comprising a step of forming a cut-out in the fold portion of the heat sink to define opposed arms extending from the first planar portion to the second planar portion.

25. The method of claim 22, wherein the step of forming the heat sink further comprises the steps of bending the fold portion to a position that is generally transverse to the first planar portion, and bending the second planar portion to a position that is generally transverse to the fold portion and extending at least partially into the recessed portion.

26. The method of claim 22, wherein the second planar portion includes a thickness, and wherein the depth of the recessed portion is between 100% and 120% of the thickness of the second planar portion.

27. The method of claim 22, wherein the second planar portion includes a thickness and is positioned to maintain a gap with the recessed portion that is between 30% and 80% of the thickness of the second planar portion.
